(19) United States
(12) Patent Application Publication
(10) Pub. No.: US 2026/0214893 A1
(43) Pub. Date: Jul. 23, 2026

(54) SEMICONDUCTOR STRUCTURE AND METHOD OF MANUFACTURING THE SAME

(71) Applicant: TAIWAN SEMICONDUCTOR MANUFACTURING COMPANY LTD., HSINCHU (TW)

(72) Inventors: YUN-FENG KAO, NEW TAIPEI CITY (TW); MING-YEN CHUANG, HSINCHU CITY (TW); KATHERINE H. CHIANG, NEW TAIPEI CITY (TW)

(21) Appl. No.: 19/034,599

(22) Filed: Jan. 23, 2025

(51) Int. Cl. H10B 41/30; H10D 64/01; H10D 64/23; H10D 64/27

(52) U.S. Cl. CPC H10B 41/30; H10D 64/031; H10D 64/251; H10D 64/512

(57) ABSTRACT

A semiconductor structure includes a first dielectric layer, a first gate structure in the first dielectric layer, a second gate structure in the first dielectric layer, and a conductive structure in the first dielectric layer and disposed under the first gate structure and the second gate structure. The first gate structure is coupled to the conductive structure, and the second gate structure is separated from the first gate structure and the conductive structure.

### BACKGROUND

Semiconductor structures including memory devices are used in a wide variety of applications. One type of memory cell includes a dynamic random access memory (DRAM) cell. Although a DRAM memory cell array may provide memory for caching and other functions in a back end region of a semiconductor device, data stored in the DRAM memory cell array is lost when power is removed from the semiconductor device due to a volatile nature of DRAM.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a cross-sectional view of a semiconductor structure in accordance with some embodiments of the present disclosure.

FIG. 2 is a cross-sectional view of a semiconductor structure in accordance with some embodiments of the present disclosure.

FIG. 3 is a cross-sectional view of a semiconductor structure in accordance with some embodiments of the present disclosure.

FIG. 4 is a cross-sectional view of a semiconductor structure in accordance with some embodiments of the present disclosure.

FIG. 5 is a flow diagram of a method of manufacturing a semiconductor structure in accordance with some embodiments of the present disclosure.

FIGS. 6 to 14 are schematic cross-sectional views of one or more stages of the method of manufacturing a semiconductor structure in accordance with some embodiments of the present disclosure.

FIG. 15 is a flow diagram of a method of manufacturing a semiconductor structure in accordance with some embodiments of the present disclosure.

FIGS. 16 to 23 are schematic cross-sectional views of one or more stages of the method of manufacturing a semiconductor structure in accordance with some embodiments of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features are not in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, although the terms such as “first,” “second” and “third” describe various elements, components, regions, layers and/or sections, these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the normal deviation found in the respective testing measurements. Also, as used herein, the terms “substantially,” “approximately” and “about” generally mean within a value or range that can be contemplated by people having ordinary skill in the art. Alternatively, the terms “substantially,” “approximately” and “about” mean within an acceptable standard error of the mean when considered by one of ordinary skill in the art. People having ordinary skill in the art can understand that the acceptable standard error may vary according to different technologies.

Other than in the operating/working examples, or unless otherwise expressly specified, all of the numerical ranges, amounts, values and percentages such as those for quantities of materials, durations of time, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

A semiconductor device may include a non-volatile memory cell structure that may be formed in a back end region of a semiconductor device. The non-volatile memory cell structure may include a floating gate, a gate structure and a word line conductive structure surrounded by a dielectric layer. The gate structure and the word line conductive structure are separated by the dielectric layer, which results in the gate structure being a floating gate structure. This enables a charge to be selectively stored on the gate structure, even when power is removed from the word line conductive structure. When the non-volatile memory cell structure is provided with a volatile memory cell structure (e.g., a DRAM memory cell structure) in the back end region of the semiconductor device, both caching and long-term storage may be performed in the back end region.

In the present disclosure, a semiconductor structure and a method of manufacturing a semiconductor structure are provided. A semiconductor device includes a first dielectric layer, a first gate structure and a second gate structure in the first dielectric layer, and a conductive structure in the first dielectric layer and disposed under the first gate structure and the second gate structure.

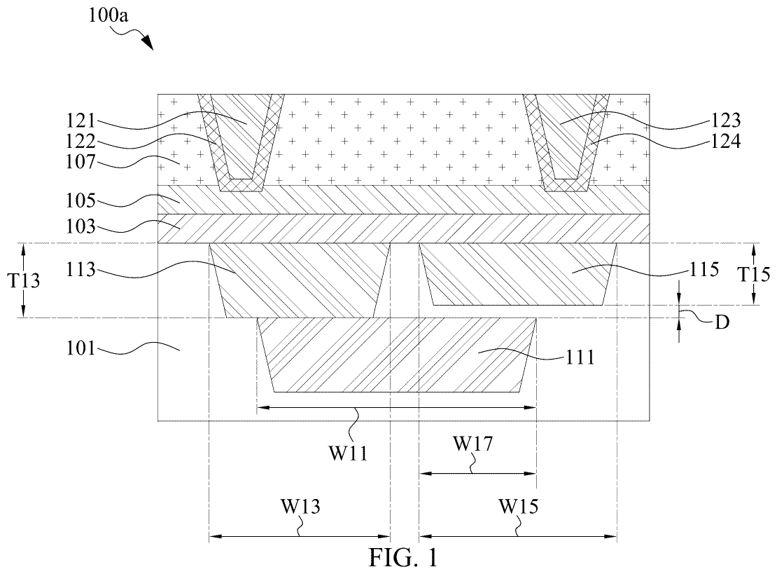

FIG. 1 is a schematic cross-sectional view illustrating a semiconductor structure according to aspects of the present disclosure in some embodiments. Referring to FIG. 1, the semiconductor structure 100a includes a first dielectric layer 101, a first gate structure 113 and a second gate structure 115 in the first dielectric layer 101. The semiconductor structure 100a further includes a conductive structure 111 in the first dielectric layer 101 and disposed under the first gate structure 113 and the second gate structure 115. FIG. 1 illustrates a back end region or a back end of line (BEOL) region of the semiconductor structure 100a. In some embodiments, a non-volatile memory structure is included in one or more back end layers of the semiconductor structure 100a. In some embodiments, the semiconductor structure 100a includes a non-volatile memory cell structure configured to selectively store an electrical charge in the first gate structure 113. In some embodiments, the non-volatile memory cell structure includes the conductive structure 111, the first gate structure 113 and the second gate structure 115 of the present disclosure.

In some embodiments, the first dielectric layer 101 includes one or more low dielectric constant (low-k) dielectric materials such as a silicon oxide (SiOₓ), fluoride-doped silicate glass (FSG), and/or another low-k dielectric material.

The conductive structure 111 is disposed within the first dielectric layer 101. In some embodiments, the conductive structure 111 serves as a word line conductive structure. In some embodiments, the conductive structure 111 is disposed below and/or under a transistor structure including the first gate structure 113. In some embodiments, the conductive structure 111 may also be referred to as an access line conductive structure, a select line conductive structure, an address line conductive structure, and/or a row line conductive structure, among other examples. In some embodiments, the conductive structure 111 includes one or more conductive materials, such as one or more metals, one or more metal alloys, and/or one or more other types of conductive materials. Examples include copper (Cu), cobalt (Co), ruthenium (Ru), titanium (Ti), tungsten (W), gold (Au), and/or silver (Ag), among other examples.

The first gate structure 113 is disposed in the first dielectric layer 101 and over the conductive structure 111. In some embodiments, the first gate structure 113 and the conductive structure 111 are in direct physical contact, such that a current or a voltage may be directly applied to the first gate structure 113 from the conductive structure 111. In some embodiments, the first gate structure 113 is a common gate structure. In some embodiments, the first gate structure 113 include a gate electrode, which may include polysilicon (e.g., polycrystalline silicon), one or more conductive materials, one or more high-k materials, and/or a combination thereof.

The second gate structure 115 is disposed in the first dielectric layer 101 and adjacent to the first gate structure 113, and the conductive structure 111 is overlapped by the first gate structure 113 and the second gate structure 115 from a plan view. In some embodiments, the second gate structure 115 is separated from the conductive structure 111 and the first gate structure 113. At least a first portion of the first dielectric layer 101 is disposed between the second gate structure 115 and the conductive structure 111, and at least a second portion of the first dielectric layer 101 is disposed between the first gate structure 113 and the second gate structure 115. In some embodiments, the second gate structure 115 serves as a floating gate structure. In some embodiments, the second gate structure 115 include a gate electrode, which may include polysilicon (e.g., polycrystalline silicon), one or more conductive materials, one or more high-k materials, and/or a combination thereof. In some embodiments, the first gate structure 113 and the second gate structure 115 include a same material or different materials.

In some embodiments, a first width W13 of the first gate structure 113 is substantially equal to or greater than a second width W15 of the second gate structure 115. In order to ensure there is enough electric field to control the second gate structure 115, at least a portion of the conductive structure 111 is overlapped by the second gate structure 115 from a plan view. In some embodiments, a third width W17 of the portion is substantially greater than 5% of the second width W15 of the second gate structure 115. In some embodiments, a top surface of the first gate structure 113 is coplanar with a top surface of the second gate structure 115. In some embodiments, a first thickness T13 of the first gate structure 113 is substantially greater than a second thickness T15 of the second gate structure 115.

In some embodiments, each of the first gate structure 113 and the second gate structure 115 is quadrilateral from a top view perspective. The first gate structure 113 and the second gate structure 115 can be, but are not limited to, round, oval, rectangular, square or another desired shape.

In some embodiments, a distance D between the conductive structure 111 and the second gate structure 115 is greater than 0. In some embodiments, the distance D is substantially greater than 3% and less than 20% of the second thickness T15 of the second gate structure 115. In some embodiments, a sum of the distance D and the second thickness T15 of the second gate structure 115 is substantially equal to the first thickness T13 of the first gate structure 113.

In some embodiments, a gate dielectric 103 is disposed over the first gate structure 113, the second gate structure 115 and the first dielectric layer 101. In some embodiments, the gate dielectric 103 is in contact with the first gate structure 113 and the second gate structure 115. In some embodiments, the gate dielectric 103 covers the first gate structure 113 and the second gate structure 115. The gate dielectric 103 may include one or more dielectric materials, including high dielectric constant (high-k) materials such as hafnium silicate (HfOₓSi), zirconium silicate (ZrSiOₓ), hafnium oxide (HfOₓ), zirconium oxide (ZrOₓ), or the like.

In some embodiments, a channel layer 105 is disposed over the gate dielectric 103. The channel layer 105 may include one or more semiconductor materials, such as silicon (Si), germanium (Ge), doped silicon, doped germanium, indium zinc oxide (InZnO), indium tin oxide (InSnO), indium oxide (InₓO_{y} such as In₂O₃), gallium oxide (GaₓO_{y} such as Ga₂O₃), indium gallium zinc oxide (InGaZnO), zinc oxide (ZnO), aluminum zinc oxide (AlₓO_{y}Zn_{z} such as Al₂O₅Zn₂), aluminum doped zinc oxide, titanium oxide (TiOₓ), III-V semiconductor materials, and/or combinations (e.g., alloys or stacked layers) of semiconductor materials, among other examples. This enables a conductive channel to be selectively formed in the channel layer 105 based on a current or a voltage being applied to the first gate structure 113. In some embodiments, the gate dielectric 103 is sandwiched between the first gate structure 113 and the channel layer 105, such that the first gate structure 113 can be capacitively coupled to the channel layer 105 through the gate dielectric 103.

In some embodiments, a second dielectric layer 107 is disposed over the channel layer 105. In some embodiments, a first dielectric constant of the first dielectric layer 101 is similar to or different from a second dielectric constant of the second dielectric layer 107. In some embodiments, the second dielectric layer 107 includes one or more low dielectric constant (low-k) dielectric materials such as a silicon oxide (SiOₓ), fluoride-doped silicate glass (FSG), and/or another low-k dielectric material. In some embodiments, the first dielectric layer 101 and the second dielectric layer 107 include a same material or different materials.

In some embodiments, source/drain regions 121, 123 are disposed on the channel layer 105 and within the second dielectric layer 107. In some embodiments, the source/drain regions 121, 123 are laterally spaced apart from each other, such that the conductive structure 111 can be located between the source/drain regions 121, 123 from a top view. The source/drain regions 121, 123, as used herein, may refer to a source region, a drain region, or both a source region and a drain region, depending on the context. The source/drain regions 121, 123 may be electrically coupled to the channel layer 105 such that current is selectively permitted to flow between the source/drain regions 121, 123 through the channel layer 105. The source/drain regions 121, 123 may each include one or more semiconductor materials, such as silicon (Si), germanium (Ge), doped silicon, and/or doped germanium, among other examples.

In some embodiments, one or more liner layers 122, 124 are respectively disposed between the source/drain regions 121, 123 and the second dielectric layer 107 and between the source/drain regions 121, 123 and the channel layer 105. The liner layer(s) 122, 124 may include adhesion liners (e.g., liners that are included to promote adhesion between the second dielectric layer 107 and the source/drain regions 121, 123, and to reduce dopant diffusion into the second dielectric layer 107 from the source/drain regions 121, 123), barrier layers (e.g., layers that are included to reduce dopant diffusion into the second dielectric layer 107 from the source/drain regions 121, 123), and/or another type of liner layers.

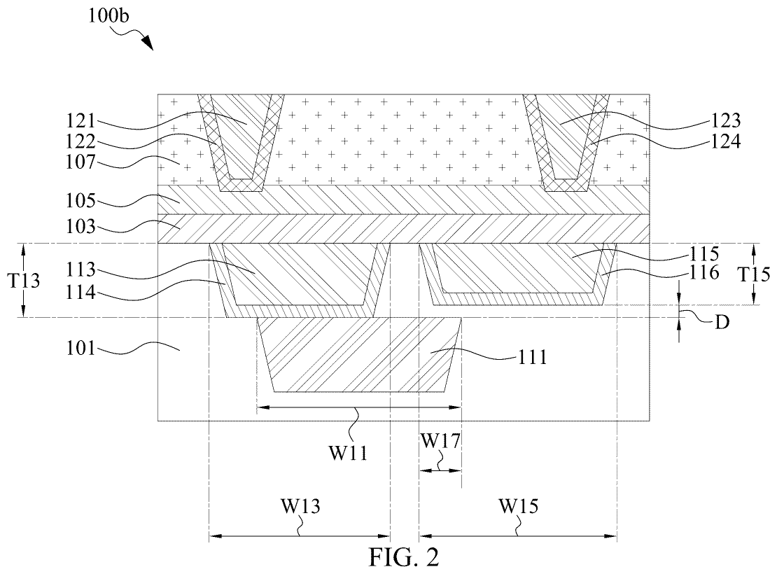

FIG. 2 is a schematic cross-sectional view illustrating a semiconductor structure according to aspects of the present disclosure in some embodiments. A semiconductor structure 100b illustrated in FIG. 2 is similar to the semiconductor structure 100a illustrated in FIG. 1, except the semiconductor structure 100b shown in FIG. 2 further includes liner layers 114, 116, and the configuration of the conductive structure 111 is different.

In some embodiments, referring to FIG. 2, regarding the portion of the conductive structure 111 overlapped by the second gate structure 115 from a plan view, the third width W17 of the portion is substantially greater than 5% and less than 50% of the second width W15 of the second gate structure 115. In some embodiments, the third width W17 of the portion is substantially greater than 5% and less than 30% of the second width W15 of the second gate structure 115.

In some embodiments, the liner layer 114 surrounds the first gate structure 113 and the liner layer 116 surrounds the second gate structure 115. In some embodiments, the liner layer 114 is disposed between the first gate structure 113 and the first dielectric layer 101 and the liner layer 116 is disposed between the second gate structure 115 and the first dielectric layer 101. Each of the first gate structure 113 and the second gate structure 115 may include a gate electrode surrounded by the liner layer 114 and the liner layer 116 respectively. The liner layer 114 is disposed between the gate electrode of the first gate structure 113 and the conductive structure 111. The liner layer 116 is disposed between the gate electrode of the second gate structure 115 and the first dielectric layer 101. The liner layers 114, 116 may include adhesion liners (e.g., liners that are included to promote adhesion between the gate electrodes of the first gate structure 113 and the second gate structure 115 and the first dielectric layer 101), barrier layers (e.g., layers that are included to reduce or minimize diffusion of the material of the gate electrodes into the first dielectric layer 101 and/or into the conductive structure 111), and/or another type of liner layers.

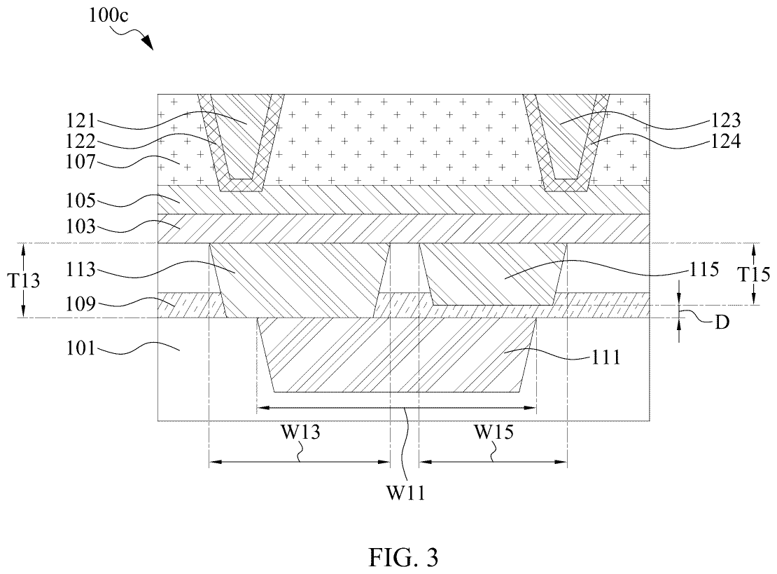

FIG. 3 is a schematic cross-sectional view illustrating a semiconductor structure according to aspects of the present disclosure in some embodiments. A semiconductor structure 100c illustrated in FIG. 3 is similar to the semiconductor structure 100a illustrated in FIG. 1, except that the semiconductor structure 100c shown in FIG. 3 further includes a third dielectric layer 109, and the configuration of the second gate structure 115 is different.

In some embodiments, referring to FIG. 3, the third dielectric layer 109 is disposed between the second gate structure 115 and the conductive structure 111. In some embodiments, the third dielectric layer 109 is disposed within the first dielectric layer 101 and in contact with the first gate structure 113, the second gate structure 115 and the conductive structure 111. In some embodiments, a portion of the first dielectric layer 101 is disposed between the third dielectric layer 109 and the gate dielectric 103. In some embodiments, the first gate structure 113 extended through the third dielectric layer 109.

In some embodiments, the first dielectric constant of the first dielectric layer 101 is different from a third dielectric constant of the third dielectric layer 109 to provide etch selectivity relative to the first dielectric layer 101. In some embodiments, the first dielectric constant is less than the third dielectric constant. In some embodiments, the third dielectric layer 109 includes one or more high dielectric constant (high-k) dielectric materials. Examples of high-k dielectric materials include dielectric materials having a dielectric constant greater than the dielectric constant of silicon oxide (approximately 3.6), such as aluminum oxide (AlOₓ), silicon carbon nitride (SiCN), and/or silicon nitride (SiₓN_{y}), among other examples.

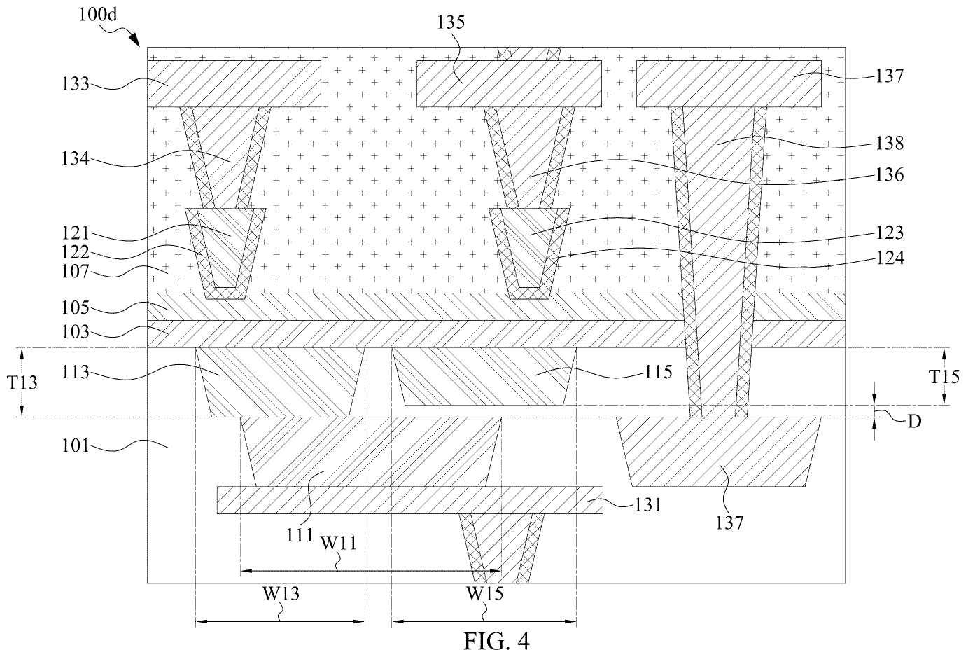

FIG. 4 is a schematic cross-sectional view illustrating a semiconductor structure according to aspects of the present disclosure in some embodiments. A semiconductor structure 100d illustrated in FIG. 4 is similar to the semiconductor structure 100a illustrated in FIG. 1, except that the semiconductor structure 100d shown in FIG. 4 further includes a first conductive layer 131, a second conductive layer 133 and a third conductive layer 135.

The source/drain regions 121, 123 may be respectively coupled to interconnect structures such as the first conductive layer 131, the second conductive layer 133 and/or the third conductive layer 135. In some embodiments, the first conductive layer 131 is disposed under and electrically connected to the conductive structure 111. In some embodiments, the second conductive layer 133 and a conductive via 134 are disposed over and electrically connected to one of the source/drain regions 121, and the third conductive layer 135 and a conductive via 136 are disposed over and electrically connected to the other one of the source/drain regions 123.

The second conductive layer 133 and the third conductive layer 135 are electrically isolated from each other. In some embodiments, one of the second conductive layer 133 and the third conductive layer 135 is configured to serve as a bit line, or is electrically connected to one of the source/drain regions 121, 123 through a corresponding one of conductive vias 134, 136. The bit line may also be referred to as a column line. In some embodiments, the other one of the second conductive layer 133 and the third conductive layer 135 is electrically connected the other one of the source/drain regions 121, 123 and to a storage capacitor (not shown) through the corresponding one of conductive vias 134, 136.

In some embodiments, the first conductive layer 131, the second conductive layer 133, the third conductive layer 135 and the conductive vias 134, 136 may each include one or more conductive materials, such as one or more metals, one or more metal alloys, and/or one or more other types of conductive materials. Examples include copper (Cu), cobalt (Co), ruthenium (Ru), titanium (Ti), tungsten (W), gold (Au), and/or silver (Ag), among other examples.

In some embodiments, the semiconductor structure 100d includes a non-volatile memory cell structure configured to selectively store an electrical charge in the first gate structure 113, and the semiconductor structure 100d further includes lines 137 and vias 138 of a BEOL interconnect.

According to some embodiments of the present disclosure, methods for manufacturing a semiconductor structure are disclosed. In some embodiments, the semiconductor structure 100c is fabricated by a method 200 or a method 300.

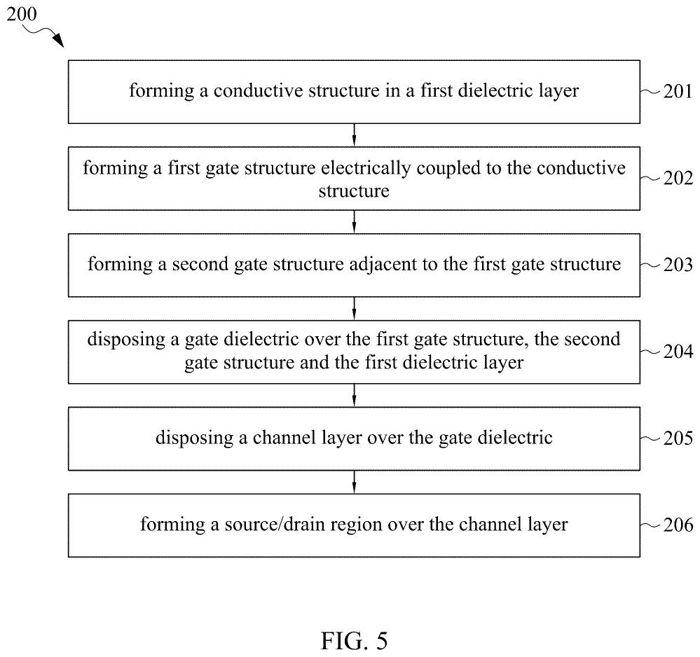

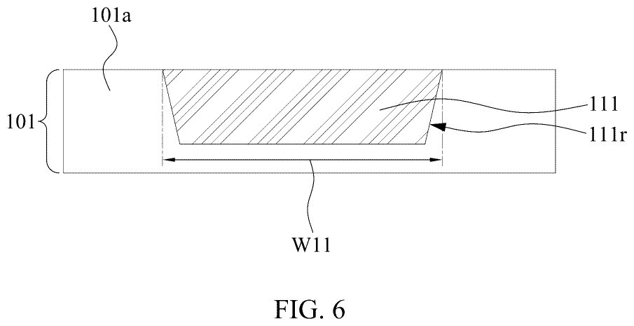

FIG. 5 is a flowchart of the method 200 in accordance with some embodiments. The method 200 includes a number of operations (201 to 206), and descriptions and illustrations are not deemed as a limitation to a sequence of the operations. Additional steps can be provided before, during, and after the operations shown in FIG. 5, and some of the operations described below can be replaced or eliminated in other embodiments of the method 200. An order of the operations may be interchangeable. FIGS. 6 to 14 are schematic cross-sectional views of one or more operations of the method 200 for manufacturing a semiconductor structure in accordance with some embodiments of the present disclosure.

The method 200 begins with operation 201. Operation 201 includes forming a conductive structure in a first dielectric layer. In some embodiments, a conductive structure 111 is formed in a first dielectric layer 101 as shown in FIG. 6.

As shown in FIG. 6, the conductive structure 111 may be formed in a first sub-layer 101a of the first dielectric layer 101. In some embodiments, the first sub-layer 101a of the first dielectric layer 101 may be formed, for example, by any acceptable deposition process, such as spin coating, chemical vapor deposition (CVD), atomic layer deposition (ALD), physical vapor deposition (PVD), laminating, the like, or a combination thereof. In some embodiments, the first dielectric layer 101 includes one or more low dielectric constant (low-k) dielectric materials.

In some embodiments, the operation 201 includes patterning the first sub-layer 101a of the first dielectric layer 101 to form a first opening 111r, and the conductive structure 111 is disposed within the first opening 111r. In some embodiments, a photoresist (not shown) is formed over the first sub-layer 101a of the first dielectric layer 101. The photoresist may be formed by spin coating and may be exposed to light for patterning. The patterning operation forms the first opening 111r through the photoresist to expose portions of the first sub-layer 101a of the first dielectric layer 101. In some embodiments, the portions of the first sub-layer 101a of the first dielectric layer 101 exposed by the photoresist are removed by an etching operation to form the first opening 111r. The etching operation includes a plasma etch technique, a wet chemical etch technique, and/or another type of etch technique. In some embodiments, a conductive material is deposited in the first opening 111r to form the conductive structure 111, and a planarization process, such as a CMP process or a mechanical grinding process, is performed to planarize top surfaces of the first sub-layer 101a of the first dielectric layer 101 and the conductive structure 111.

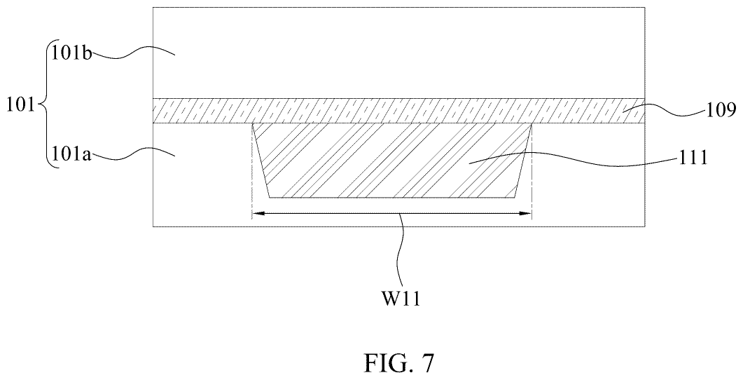

In some embodiments, referring to FIG. 7, a second sub-layer 101b of the first dielectric layer 101 is formed on the first sub-layer 101a of the first dielectric layer 101 and over the conductive structure 111. In some embodiments, the second sub-layer 101b of the first dielectric layer 101 includes a material same as a material of the first sub-layer 101a of the first dielectric layer 101 and redefines the top surface 101a of the first dielectric layer 101. In some embodiments, the second sub-layer 101b of the first dielectric layer 101 may be formed, for example, by any acceptable deposition process, such as spin coating, chemical vapor deposition (CVD), atomic layer deposition (ALD), physical vapor deposition (PVD), laminating, the like, or a combination thereof.

In some embodiments, a third dielectric layer 109 is formed over the first sub-layer 101a of the first dielectric layer 101 and the conductive structure 111 before the formation of the second sub-layer 101b of the first dielectric layer 101. In some embodiments, the third dielectric layer 109 is formed between the first sub-layer 101a and the second sub-layer 101b of the first dielectric layer 101. In some embodiments, the third dielectric layer 109 may be formed, for example, by any acceptable deposition process, such as spin coating, chemical vapor deposition (CVD), atomic layer deposition (ALD), physical vapor deposition (PVD), laminating, the like, or a combination thereof.

In some embodiments, a first dielectric constant of the second sub-layer 101b of the first dielectric layer 101 is different from a third dielectric constant of the third dielectric layer 109 to provide etch selectivity relative to the second sub-layer 101b of the first dielectric layer 101. In some embodiments, the third dielectric constant is greater than the first dielectric constant. In some embodiments, the third dielectric layer 109 includes one or more high dielectric constant (high-k) dielectric materials.

In some embodiments, a thickness of the third dielectric layer 109 is less than a thickness of the first sub-layer 101a of the first dielectric layer 101. In some embodiments, a thickness of the third dielectric layer 109 is less than a thickness of the second sub-layer 101b of the first dielectric layer 101.

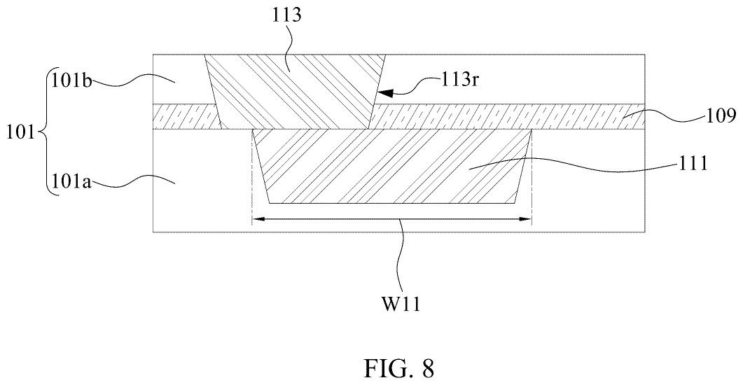

The method 200 continues with operation 202. Operation 202 includes forming a first gate structure electrically coupled to the conductive structure. In operation 202, referring to FIG. 8, a first gate structure 113 is formed within the first dielectric layer 101 and over the conductive structure 111. In some embodiments, the first gate structure 113 is formed within and extends through the second sub-layer 101b of the first dielectric layer 101 and the third dielectric layer 109.

In some embodiments, the operation 202 includes patterning the second sub-layer 101b of the first dielectric layer 101 to form a first recess 113r, and the first gate structure 113 is disposed within the first recess 113r. In some embodiments, a portion of the conductive structure 111 is exposed through the first recess 113r, and another portion of the conductive structure 111 is covered by the second sub-layer 101b of the first dielectric layer 101 and the third dielectric layer 109. In some embodiments, a photoresist (not shown) is formed over the second sub-layer 101b of the first dielectric layer 101. The photoresist may be formed by spin coating and may be exposed to light for patterning. The patterning operation forms the first recess 113r through the photoresist to expose portions of the second sub-layer 101b of the first dielectric layer 101. In some embodiments, the portions of the second sub-layer 101b of the first dielectric layer 101 exposed by the photoresist are removed by an etching operation to form the first recess 113r. The etch operation includes a plasma etch technique, a wet chemical etch technique, and/or another type of etch technique. In some embodiments, a conductive material is deposited in the first recess 113r to form the first gate structure 113, and a planarization process, such as a CMP process or a mechanical grinding process, is performed to planarize top surfaces of the second sub-layer 101b of the first dielectric layer 101 and the first gate structure 113.

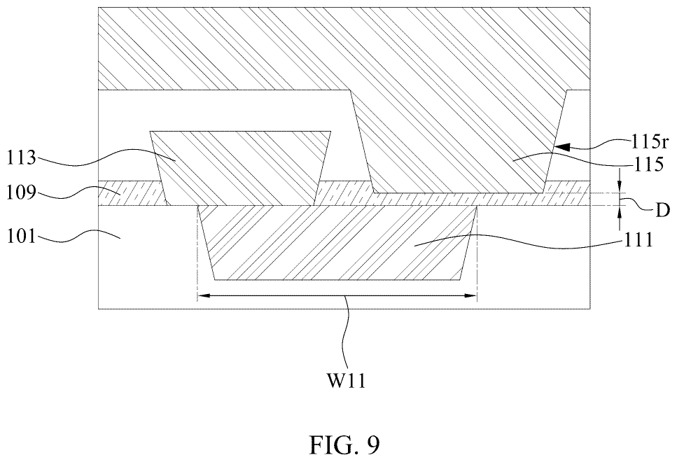

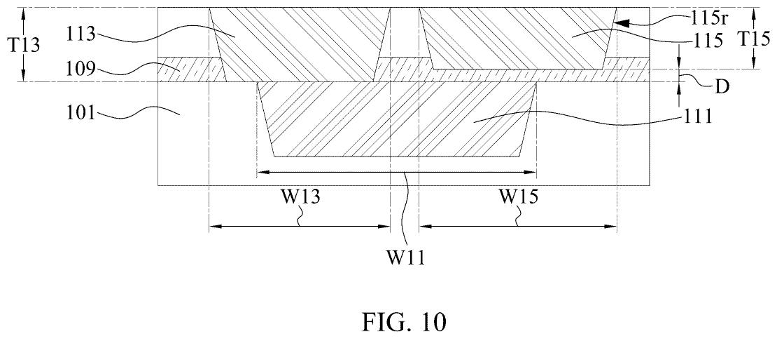

The method 200 continues with operation 203. Operation 203 includes forming a second gate structure adjacent to the first gate structure. In operation 203, referring to FIGS. 9 to 10, a second gate structure 115 is formed adjacent to the first gate structure 113, wherein at least a portion of the first dielectric layer 101 is disposed between the first gate structure 113 and the second gate structure 115. The second gate structure 115 is separated from the conductive structure 111 and the first gate structure 113 by the first dielectric layer 101, and at least a portion of the conductive structure 111 is overlapped by the second gate structure 115 from a plan view. In some embodiments, the formation of the first gate structure 113 is performed prior to the formation of the second gate structure 115.

In some embodiments, the operation 203 includes patterning the second sub-layer 101b of the first dielectric layer 101 to form a second recess 115r adjacent to the first recess 113r, and the second gate structure 115 is disposed within the second recess 115r. A distance D between the second gate structure 115 and the conductive structure 111 is greater than 0. In some embodiments, a first width W13 of the first gate structure 113 is substantially greater than or equal to a second width W15 of the second gate structure 115. In some embodiments, a first thickness T13 of the first gate structure 113 is substantially greater than a second thickness T15 of the second gate structure 115. In some embodiments, the first gate structure 113 is formed before the formation of the second recess 115r.

In some embodiments, a photoresist (not shown) is formed over the second sub-layer 101b of the first dielectric layer 101. The photoresist may be formed by spin coating and may be exposed to light for patterning. The patterning operation forms the second recess 115r through the photoresist to expose portions of the second sub-layer 101b of the first dielectric layer 101. In some embodiments, referring to FIG. 9, the portions of the second sub-layer 101b of the first dielectric layer 101 exposed by the photoresist are removed by an etching operation to form the second recess 115r. The etch operation includes a plasma etch technique, a wet chemical etch technique, and/or another type of etch technique. In some embodiments, a portion of the second sub-layer 101b of the first dielectric layer 101 or a portion of the third dielectric layer 109 is exposed through the second recess 115r.

In some embodiments, referring to FIGS. 9 and 10, a conductive material is deposited. Accordingly, the second recess 115r is filled with the conductive material. In some embodiments, the conductive material may cover the first dielectric layer 101, as shown in FIG. 9. Subsequently, a planarization process, such as a CMP process or a mechanical grinding process, is performed to remove superflous conductive material. Accordingly a second gate structure 115 is formed. In some embodiments, the first gate structure 113 is formed before the formation of the second gate structure 115. Further, top surfaces of the second sub-layer 101b of the first dielectric layer 101, the first gate structure 113 and the second gate structure 115 may be coplanar by the planarization process, as shown in FIG. 10. In some embodiments, the first gate structure 113 has a first width W13 and the second gate structure 115 has a second width W15, and the first width W13 of the first gate structure 113 is substantially equal to or greater than the second width W15 of the second gate structure 115. In some embodiments, the first width W13 is substantially equal to the second width W15.

The method 200 continues with operations 204 and 205. Operation 204 includes disposing a gate dielectric over the first gate structure, the second gate structure and the first dielectric layer. Operation 205 includes disposing a channel layer over the gate dielectric.

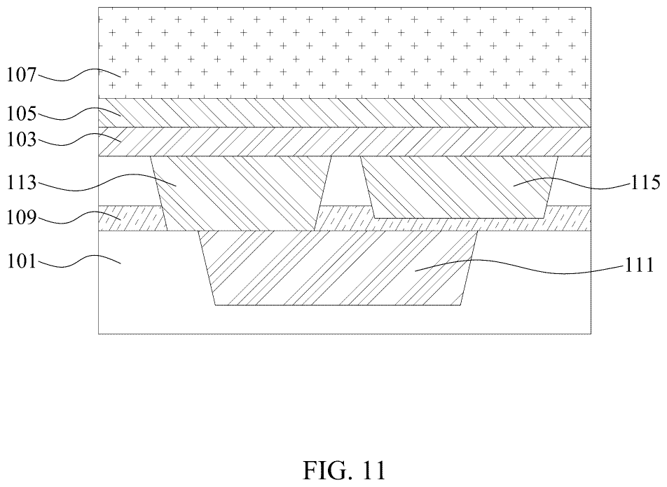

In operation 204, referring to FIG. 11, a gate dielectric 103 is disposed over the first gate structure 113, the second gate structure 115 and the first dielectric layer 101. In some embodiments, the method 200 further includes planarizing the first gate structure 113, the second gate structure 115 and the first dielectric layer 101 before the deposition of the gate dielectric 103. In operation 205, a channel layer 105 is disposed over the gate dielectric 103. Each of the gate dielectric 103 and the channel layer 105 may be formed, for example, by any acceptable deposition process, such as spin coating, CVD, ALD, PVD, laminating, the like, or a combination thereof.

In some embodiments, the method 200 further includes disposing a second dielectric layer 107 over the channel layer 105. The second dielectric layer 107 may be formed, for example, by any acceptable deposition process, such as spin coating, CVD, ALD, PVD, laminating, the like, or a combination thereof.

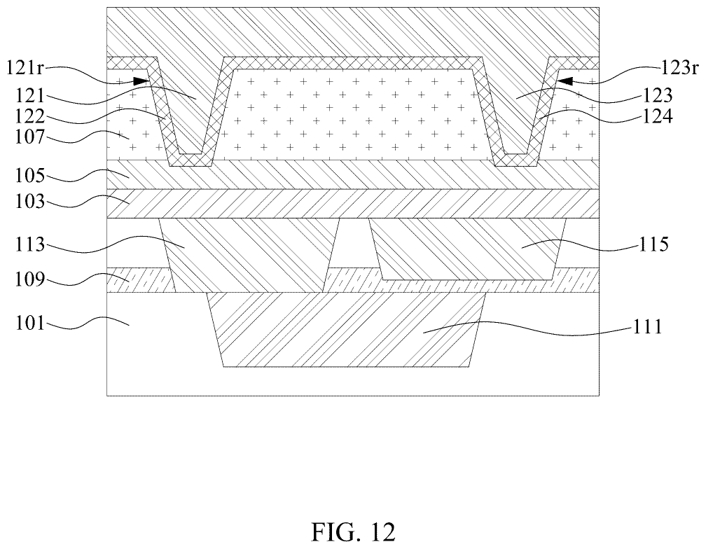

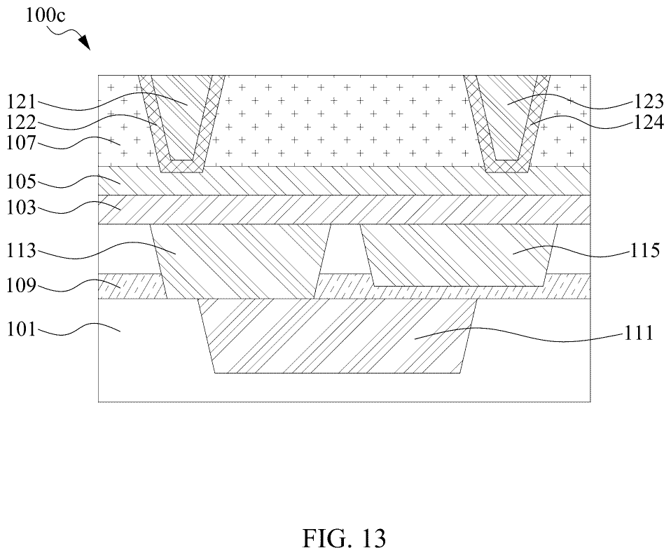

The method 200 continues with operation 206. Operation 206 includes forming a source/drain region over the channel layer 105. In operation 206, referring to FIGS. 12 and 13, source/drain regions 121, 123 are formed over the channel layer 105.

In operation 206, the source/drain regions 121, 123 are formed within and extend through the second dielectric layer 107. One of the source/drain regions 121 is formed over the first gate structure 113, and another one of the source/drain regions 123 is formed over the second gate structure 115.

In some embodiments, the operation 206 includes patterning the second dielectric layer 107 to form a third recess 121r and a fourth recess 123r, and one of the source/drain regions 121 is disposed within the third recess 121r, and another one of the source/drain regions 123 is disposed within the fourth recess 123r. In some embodiments, a photoresist (not shown) is formed over the second dielectric layer 107. The photoresist may be formed by spin coating and may be exposed to light for patterning. The patterning operation forms the third recess 121r and the fourth recess 123r through the photoresist to expose portions of the second dielectric layer 107 and the channel layer 105. In some embodiments, the portions of second dielectric layer 107 and the channel layer 105 exposed by the photoresist are removed by an etching operation to form the third recess 121r and the fourth recess 123r. The etching operation includes a plasma etch technique, a wet chemical etch technique, and/or another type of etch technique.

In some embodiments, one or more liner layers 122, 124 are respectively disposed within and conformal to the third recess 121r and the fourth recess 123r. In some embodiments, the liner layer 122 is formed between one of the source/drain regions 121 and the channel layer 105, and the liner layer 124 is formed between another one of the source/drain regions 123 and the channel layer 105.

In some embodiments, one or more semiconductor materials are deposited in the third recess 121r and the fourth recess 123r and over the liner layers 122, 124 to form the source/drain regions 121, 123 respectively, and a planarization process, such as a CMP process or a mechanical grinding process, is performed to planarize top surfaces of second dielectric layer 107, the liner layers 122, 124, and the source/drain regions 121, 123. In some embodiments, a semiconductor structure 100c is formed.

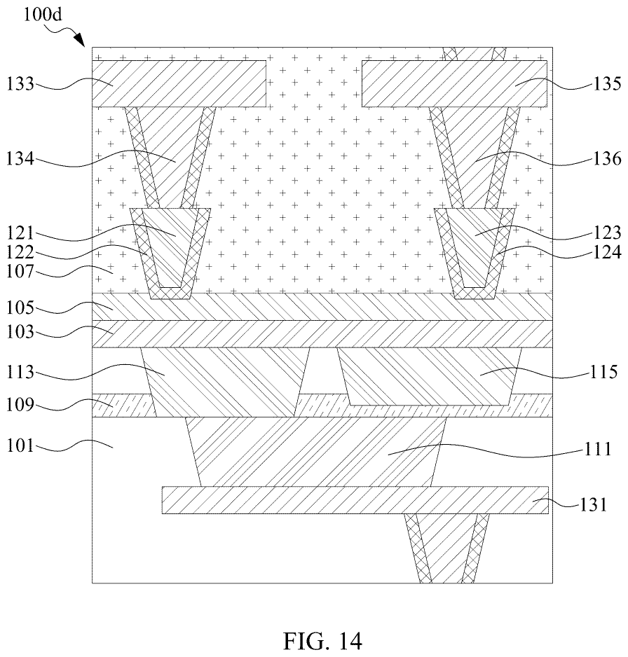

In some embodiments, referring to FIG. 14, the method further includes forming a first conductive layer 131 disposed under and electrically connected to the conductive structure 111. In some embodiments, the method further includes disposing a dielectric material over the source/drain regions 121, 123 to redefine the top surface of the second dielectric layer 107. In some embodiments, the method further includes forming a second conductive layer 133 and a conductive via 134 over and electrically connected to one of the source/drain regions 121. In some embodiments, the method further includes forming a third conductive layer 135 and a conductive via 136 over and electrically connected to another one of the source/drain regions 123. In some embodiments, a semiconductor structure 100d is formed.

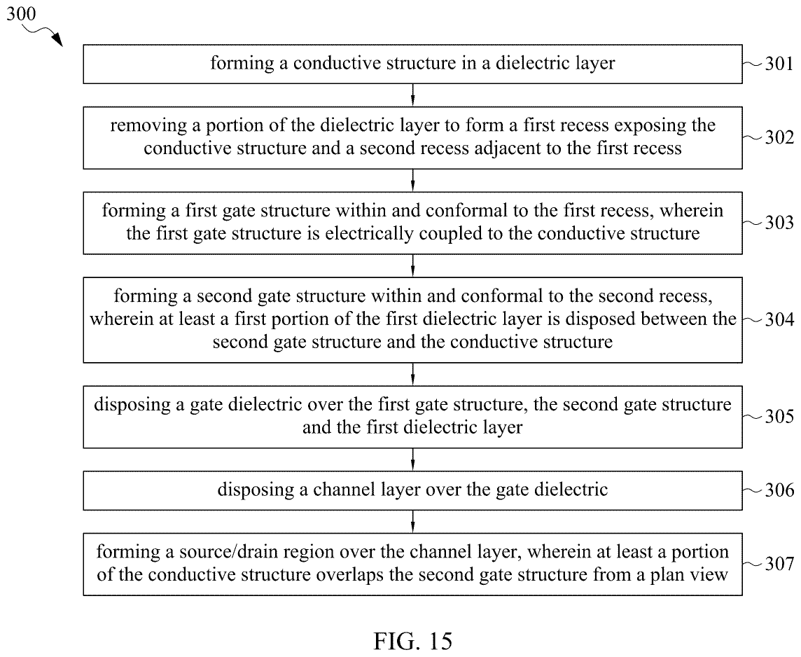

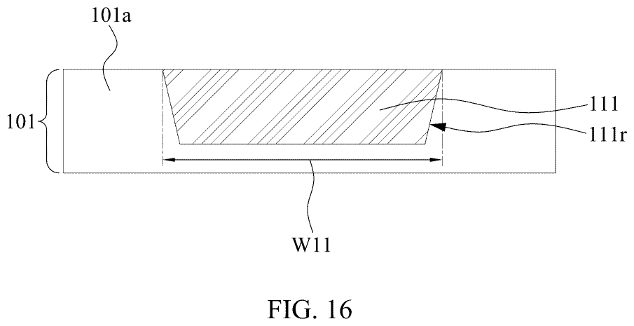

FIG. 15 is a flowchart of the method 300 in accordance with some embodiments. The method 300 includes a number of operations (301 to 307), and descriptions and illustrations are not deemed as a limitation to a sequence of the operations. Additional steps can be provided before, during, and after the operations shown in FIG. 15, and some of the operations described below can be replaced or eliminated in other embodiments of the method 300. An order of the operations may be interchangeable. FIGS. 16 to 23 are schematic cross-sectional views of one or more operations of the method 300 for manufacturing a semiconductor structure in accordance with some embodiments of the present disclosure.

The method 300 begins with operation 301. Operation 301 includes forming a conductive structure in a dielectric layer. In some embodiments, a conductive structure 111 is formed in a first dielectric layer 101 as shown in FIG. 16.

In some embodiments, operation 301 of the method 300 is similar to operation 201 of the method 200. In some embodiments, a first sub-layer 101a, the first dielectric layer 101 and the conductive structure 111 are similar to the first sub-layer 101a, the first dielectric layer 101 and the conductive structure 111 shown in FIG. 6, and detailed descriptions of such operation are omitted herein for brevity.

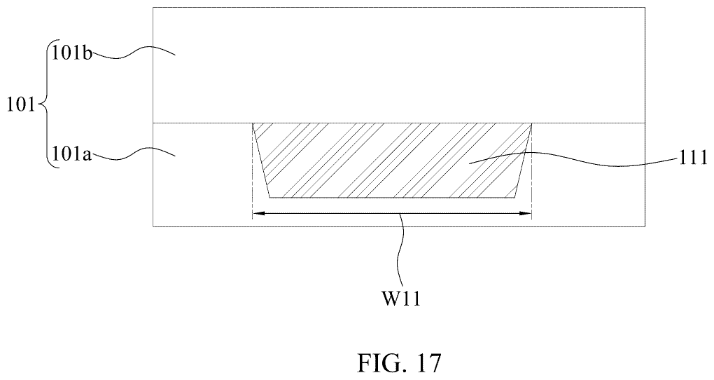

In some embodiments, referring to FIG. 17, a second sub-layer 101b of the first dielectric layer 101 is formed on the first sub-layer 101a of the first dielectric layer 101 and over the conductive structure 111. In some embodiments, the second sub-layer 101b is similar to the second sub-layer 101b shown in FIG. 7, and detailed descriptions of such operation are omitted for brevity. In some embodiments, a third dielectric layer 109 similar to the third dielectric layer 109 shown in FIG. 7 is disposed between the first sub-layer 101a and the second sub-layer 101b. In some embodiments, the third dielectric layer 109 is omitted.

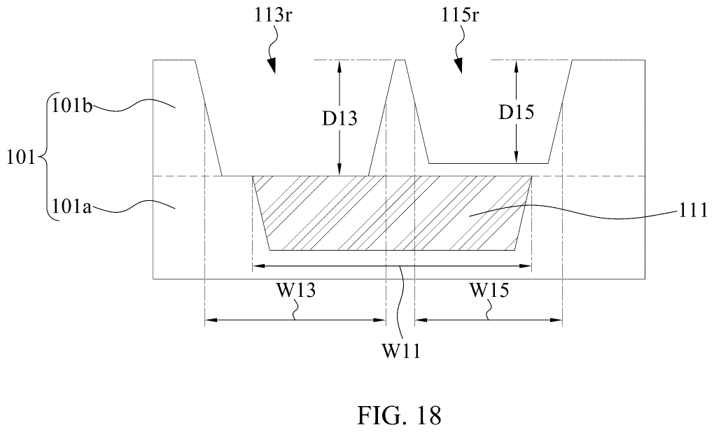

The method 300 continues with operation 302. Operation 302 includes removing a portion of the first dielectric layer to form a first recess exposing the conductive structure and a second recess adjacent to the first recess. In some embodiments, referring to FIG. 18, the portion of the first dielectric layer 101 is removed to form the first recess 113r exposing the conductive structure 111 and the second recess 115r adjacent to the first recess 113r. In some embodiments, the formation of the first recess and the formation of the second recess are performed simultaneously.

In some embodiments, a photoresist (not shown) is formed over the second sub-layer 101b of the first dielectric layer 101. The photoresist may be formed by spin coating and may be exposed to light for patterning. The patterning operation forms the first recess 113r having a first width W13 and the second recess 115r having a second W15 through the photoresist to expose portions of the second sub-layer 101b of the first dielectric layer 101. In some embodiments, the first width W13 is substantially greater than the second width W15. In some embodiments, the portions of the second sub-layer 101b of the first dielectric layer 101 exposed by the photoresist are removed by an etching operation to form the first recess 113r and the second recess 115r simultaneously. The etching operation includes a plasma etch technique, a wet chemical etch technique, and/or another type of etch technique.

In some embodiments, the first recess 113r extends through the second sub-layer 101b of the first dielectric layer 101, and the second recess 115r is defined by the second sub-layer 101b of the first dielectric layer 101. In some embodiments, in order to form the first recess 113r and the second recess 115r having different depths at the same time, the first width W13 of the first recess 113r is substantially greater than the second width W15 of the second recess 115r, so that a first depth D13 of the first recess 113r is substantially greater than a second depth D15 of the second recess 115r.

The method 300 continues with operation 303 and operation 304. Operation 303 includes forming a first gate structure within and conformal to the first recess, wherein the first gate structure is electrically coupled to the conductive structure. Operation 304 includes forming a second gate structure within and conformal to the second recess.

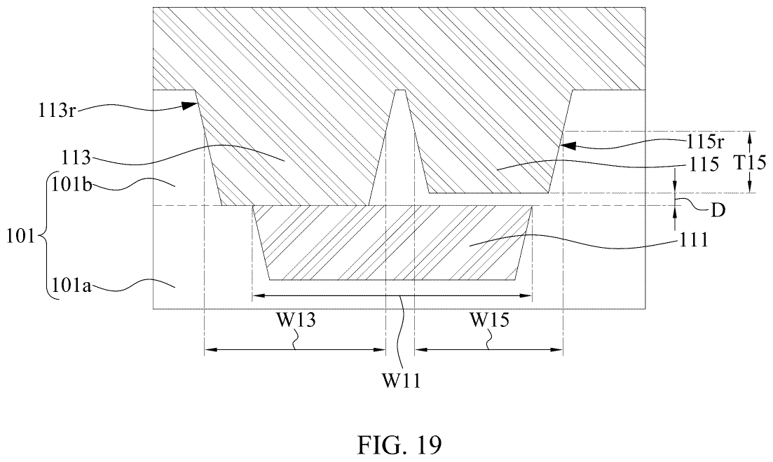

In some embodiments, referring to FIG. 19, the first gate structure 113 is formed within and conformal to the first recess 113r, wherein the first gate structure 113 is electrically coupled to the conductive structure 111. In some embodiments, the second gate structure 115 is formed within and conformal to the second recess 115r, wherein at least a portion of the first dielectric layer 101 is disposed between the second gate structure 115 and the conductive structure 111. In some embodiments, at least a portion of the conductive structure 111 is overlapped by the second gate structure 115 from a plan view.

In some embodiments, at least a portion of the second sub-layer 101b of the first dielectric layer 101 is disposed between the second gate structure 115 and the conductive structure 111, and a distance D between the second gate structure 115 and the conductive structure 111 is greater than 0. In some embodiments, at least a portion of the second sub-layer 101b of the first dielectric layer 101 is disposed between the second gate structure 115 and the first gate structure 113. In some embodiments, the formation of the first gate structure 113 and the formation of the second gate structure 115 are performed simultaneously.

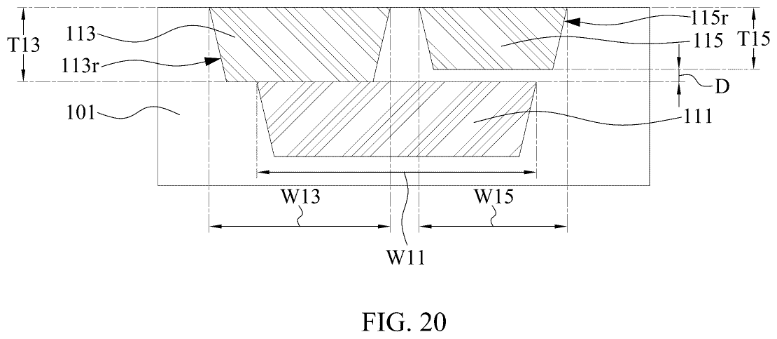

In some embodiments, a conductive material is deposited in the first recess 113r and the second recess 115r. Accordingly, the first recess 113r and the second recess 115r is filled with the conductive material. In some embodiments, the conductive material may cover the first dielectric layer 101, as shown in FIG. 19. Subsequently, a planarization process, such as a CMP process or a mechanical grinding process, is performed to remove superflous conductive material. Accordingly a first gate structure 113 and a second gate structure 115 are formed. In some embodiments, the first gate structure 113 and the second gate structure 115 are formed simultaneously. Further, top surfaces of the second sub-layer 101b of the first dielectric layer 101, the first gate structure 113 and the second gate structure 115 may be coplanar by the planarization process, as shown in FIG. 20. In some embodiments, the first gate structure 113 and the second gate structure 115 include a same conductive material.

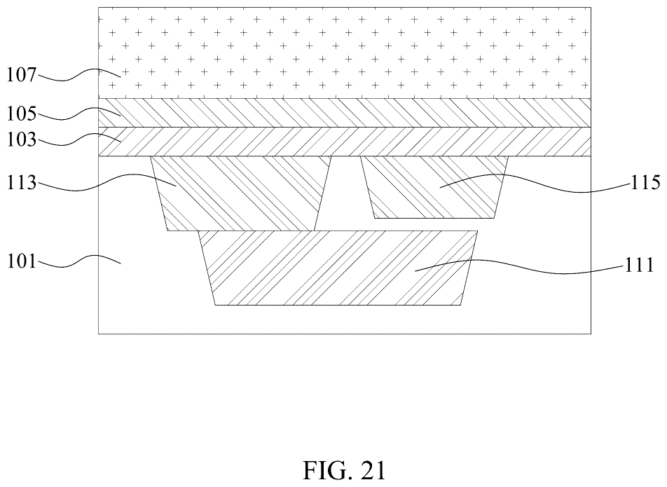

The method 300 continues with operation 305 and operation 306. Operation 305 includes disposing a gate dielectric over the first gate structure, the second gate structure and the first dielectric layer. In some embodiments, operation 305 of the method 300 is similar to operation 204 of the method 200. In some embodiments, a gate dielectric 103, the first gate structure 113, and the second gate structure 115 shown in FIG. 21 are similar to the gate dielectric 103, the first gate structure 113, and the second gate structure 115 shown in FIG. 11, and detailed descriptions of such operation are omitted for brevity. In some embodiments, operation 306 of the method 300 is similar to operation 205 of the method 200. In some embodiments, a channel layer 105 shown in FIG. 21 is similar to the channel layer 105 shown in FIG. 11, and detailed descriptions of such operation are omitted for brevity.

In some embodiments, referring to FIG. 21, the method 300 further includes disposing a second dielectric layer 107 over the channel layer 105. In some embodiments, the second dielectric layer 107 shown in FIG. 21 is similar to the second dielectric layer 107 shown in FIG. 11, and detailed descriptions of such operation are omitted for brevity.

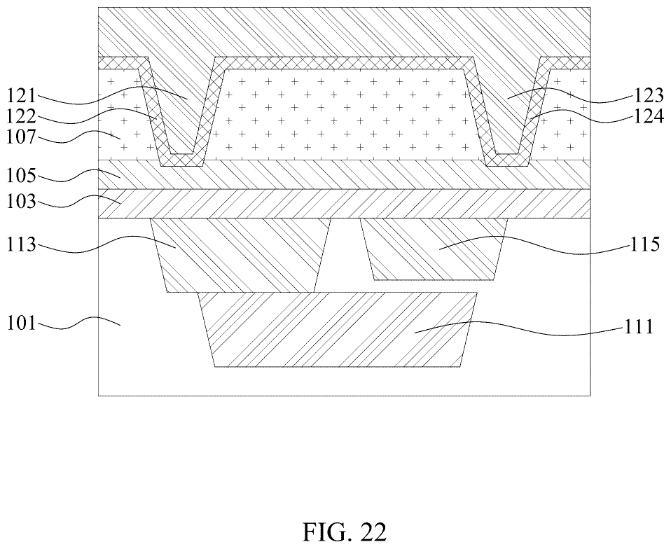

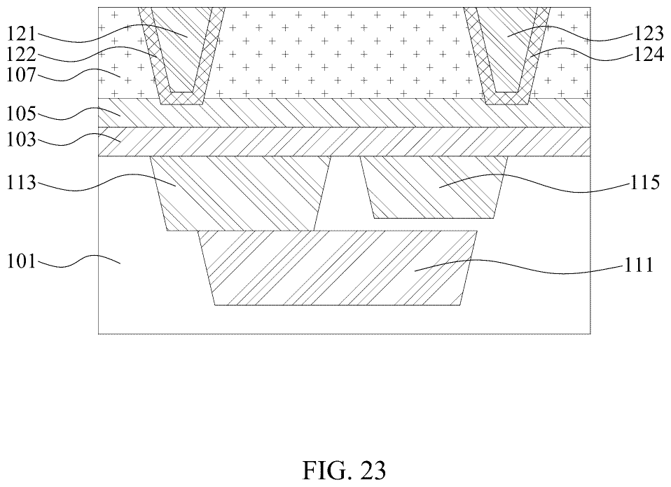

The method 300 continues with operation 307. Operation 307 includes forming a source/drain region over the channel layer. In some embodiments, operation 307 of the method 300 is similar to operation 206 of the method 200. In some embodiments, the source/drain regions 121, 123 shown in FIGS. 22 to 23 are similar to the source/drain regions 121, 123 shown in FIGS. 12 to 13, and detailed descriptions of such operation are omitted for brevity. In some embodiments, a liner layer 122 is formed between one of the source/drain regions 121 and the channel layer 105, and a liner layer 124 is formed between another one of source/drain regions 123 and the channel layer 105. The liner layers 122, 124 shown in FIGS. 22 to 23 are similar to the liner layers 122, 124 shown in FIGS. 12 to 13, and detailed descriptions of such operation are omitted for brevity. In some embodiments, a semiconductor structure 100a is formed.

In accordance with some embodiments of the disclosure, a semiconductor structure includes a first dielectric layer, a first gate structure in the first dielectric layer, a second gate structure in the first dielectric layer, and a conductive structure in the first dielectric layer and disposed under the first gate structure and the second gate structure. The first gate structure is coupled to the conductive structure, and the second gate structure is separated from the first gate structure and the conductive structure.

In accordance with some embodiments of the disclosure, a method of manufacturing a semiconductor structure includes forming a conductive structure in a first dielectric layer; forming a first gate structure electrically coupled to the conductive structure; and forming a second gate structure adjacent to the first gate structure. The method further includes disposing a gate dielectric over the first gate structure, the second gate structure and the first dielectric layer; disposing a channel layer over the gate dielectric; and forming a source/drain region over the channel layer. The second gate structure is separated from the conductive structure and the first gate structure, and at least a portion of the conductive structure is overlapped by the second gate structure from a plan view.

In accordance with some embodiments of the disclosure, a method of manufacturing a semiconductor structure includes forming a conductive structure in a dielectric layer; removing a portion of the dielectric layer to form a first recess exposing the conductive structure and a second recess adjacent to the first recess; forming a first gate structure within and conformal to the first recess, wherein the first gate structure is electrically coupled to the conductive structure; and forming a second gate structure within and conformal to the second recess, wherein at least a first portion of the first dielectric layer is disposed between the second gate structure and the conductive structure. The method further includes disposing a gate dielectric over the first gate structure, the second gate structure and the first dielectric layer; disposing a channel layer over the gate dielectric; and forming a source/drain region over the channel layer. At least a portion of the conductive structure is overlapped by the second gate structure from a plan view.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a first dielectric layer;
a first gate structure in the first dielectric layer;
a second gate structure in the first dielectric layer; and
a conductive structure in the first dielectric layer and disposed under the first gate structure and the second gate structure;
wherein the first gate structure is coupled to the conductive structure, and the second gate structure is separated from the first gate structure and the conductive structure.

2. The semiconductor structure of claim 1, wherein at least a portion of the first dielectric layer is disposed between the second gate structure and the conductive structure.

3. The semiconductor structure of claim 1, wherein the conductive structure is overlapped by the first gate structure and the second gate structure from a plan view.

4. The semiconductor structure of claim 1, further comprising:
a gate dielectric disposed over the first gate structure, the second gate structure and the first dielectric layer;
a channel layer disposed over the gate dielectric; and
a source/drain region disposed over the channel layer.

5. The semiconductor structure of claim 1, wherein a first width of the first gate structure is substantially equal to or greater than a second width of the second gate structure.

6. The semiconductor structure of claim 5, wherein a portion of the conductive structure is overlapped by the second gate structure from a plan view, and a third width of the portion is substantially greater than 5% of the second width of the second gate structure.

7. The semiconductor structure of claim 1, wherein a first thickness of the first gate structure is substantially greater than a second thickness of the second gate structure.

8. The semiconductor structure of claim 1, wherein the first gate structure is disposed adjacent to the second gate structure, and a top surface of the first gate structure is coplanar with a top surface of the second gate structure.

9. The semiconductor structure of claim 1, further comprising:
a second dielectric layer disposed between the second gate structure and the conductive structure,
wherein a first dielectric constant of the first dielectric layer is different from a second dielectric constant of the second dielectric layer.

10. The semiconductor structure of claim 1, further comprising:
a source/drain region disposed over the first gate structure;
a first conductive layer disposed under and electrically connected to the conductive structure; and
a second conductive layer disposed over and electrically connected to the source/drain region.

11. A method of manufacturing a semiconductor structure, comprising:
forming a conductive structure in a first dielectric layer;
forming a first gate structure electrically coupled to the conductive structure;
forming a second gate structure adjacent to the first gate structure;
disposing a gate dielectric over the first gate structure, the second gate structure and the first dielectric layer;
disposing a channel layer over the gate dielectric; and
forming a source/drain region over the channel layer,
wherein the second gate structure is separated from the conductive structure and the first gate structure, and at least a portion of the conductive structure is overlapped by the second gate structure from a plan view.

12. The method of claim 11, wherein the formation of the first gate structure is performed prior to the formation of the second gate structure.

13. The method of claim 11, further comprising:
planarizing the first gate structure, the second gate structure and the first dielectric layer before the deposition of the gate dielectric.

14. The method of claim 11, further comprising:
disposing a second dielectric layer over the first dielectric layer and the conductive structure before the formation of the first gate structure,
wherein at least a portion of the second dielectric layer is disposed between the second gate structure and the conductive structure.

15. The method of claim 11, further comprising:
forming a first conductive layer disposed under and electrically connected to the conductive structure; and
forming a second conductive layer disposed over and electrically connected to the source/drain region.

16. A method of manufacturing a semiconductor structure, comprising:
forming a conductive structure in a dielectric layer;
removing a portion of the dielectric layer to form a first recess exposing the conductive structure and a second recess adjacent to the first recess;
forming a first gate structure within and conformal to the first recess, wherein the first gate structure is electrically coupled to the conductive structure;
forming a second gate structure within and conformal to the second recess, wherein at least a first portion of the first dielectric layer is disposed between the second gate structure and the conductive structure;
disposing a gate dielectric over the first gate structure, the second gate structure and the first dielectric layer;
disposing a channel layer over the gate dielectric; and
forming a source/drain region over the channel layer,
wherein at least a portion of the conductive structure is overlapped by the second gate structure from a plan view.

17. The method of claim 16, wherein the formation of the first recess and the formation of the second recess are performed simultaneously, and the formation of the first gate structure and the formation of the second gate structure are performed simultaneously.

18. The method of claim 16, wherein a first width of the first recess is substantially greater than a second width of the second recess.

19. The method of claim 16, wherein a first depth of the first recess is substantially greater than a second depth of the second recess.

20. The method of claim 16, wherein the dielectric layer defines the second recess, and at least a second portion of the dielectric layer is disposed between the first gate structure and the second gate structure.
